(19) United States
(12) Patent Application Publication
(10) Pub. No.: US 2010/0109076 A1
(43) Pub. Date: May 6, 2010

(54) STRUCTURES FOR ELECTROSTATIC DISCHARGE PROTECTION

(75) Inventors: Shih-Yu Wang, Taipei City (TW); Chia-Ling Lu, Luzhou City (TW); Yan-Yu Chen, Taipei City (TW); Yu-Lien Liu, Hsinchu City (TW); Tao-Cheng Lu, Hsinchu (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Macronix International Co., Ltd., Taiwan (CN)

(21) Appl. No.: 12/264,879

(22) Filed: Nov. 4, 2008

(51) Int. Cl. H01L 29/78; H01L 21/336

(52) U.S. Cl. 257/328; 438/286; 257/E29.261; 257/E21.417

(57) ABSTRACT

A semiconductor device includes a first well region of a first conductivity, a second well region of a second conductivity type, a source region of the second conductivity type within the first well region, and a drain region of the second conductivity type at least partially within the second well region. A well contact to the first well region is coupled to the source. A first doped region of the first conductivity type and a second doped region of the second conductivity type are located in the second well region. A first transistor includes the first doped region, the second well region, and the first well region. The first transistor is coupled to a switch device. A second transistor includes the second well region, the first well region, and the source region. The first and the second transistors are configured to provide a current path during an ESD event.

### CROSS-REFERENCES TO RELATED APPLICATIONS

NOT APPLICABLE

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

The present invention is directed to integrated circuits. More particularly, the invention provides a method and device for integrated circuits having electrostatic discharge (ESD) protection structure for providing an ESD current path having a lower trigger voltage than a convention silicon controlled rectifier (SCR). Merely by way of example, the invention has been applied to LDMOS lateral double-diffused MOSFET (LDMOS), high voltage field transistors, and low voltage MOSFET for improved ESD protection. But it would be recognized that the invention has a much broader range of applicability.

Semiconductor devices in an integrated circuit are susceptible to damages caused by electro-static discharge (ESD). ESD can be induced by the motion of static electricity generated from a non-conductive surface. For example, a human body moving on a carpet may gather thousands of volts of static electricity. Moreover, in integrated circuits testing or packaging environment, even higher static electricity may be generated. The high energy pulses of the electro-static discharge (ESD) can cause severe damage to the devices in the integrated circuits.

To prevent the damage of the integrated circuits due to the electro-static discharge, an ESD protection circuit is often included in the integrated circuit. Conventionally, in an MOS or CMOS integrated circuit, the ESD protection circuit often includes parasitic bipolar junction transistor or a silicon control rectifier (SCR) which is turned on by the high voltage pulses in an ESD event. For example, in a lateral double-diffused MOSFET (LDMOS), a conventional ESD protection structure includes a p-type contact region near a drain region of the LDMOS device. As a result, a parasitic SCR is formed by the p-type contact, the n-well, the p-substrate, the source region. Such an SCR is turned on, or triggered, to provide a current discharge path, if a high voltage at the drain contact pad is high enough to cause an avalanche breakdown at the junction between the n-well and p-substrate.

Even though conventional ESD protection structures are useful in some applications, many limitations still exist. For example, conventional ESD protection structures often have high trigger voltages. In certain applications, such high trigger voltages do not provide adequate ESD protection to the integrated circuit. These and other limitations are described throughout the present specification and more particularly below.

From the above, it is seen that an improved technique for ESD protection in semiconductor devices is desired.

### BRIEF SUMMARY OF THE INVENTION

The present invention is directed to integrated circuits. More particularly, the invention provides a method and device for integrated circuits having electrostatic discharge (ESD) protection structure for providing an ESD current path having a lower trigger voltage than a conventional silicon controlled rectifier (SCR). Merely by way of example, the invention has been applied LDMOS lateral double-diffused MOSFET (LDMOS), high voltage filed transistors, and low voltage MOSFET for improved ESD protection. But it would be recognized that the invention has a much broader range of applicability.

According to a specific embodiment, the invention provides a semiconductor device which includes a first well region of a first conductivity the first well region includes a first well contact region of the first conductivity type for coupling to a first potential. The device includes a source region of the second conductivity type within the first well region and coupled to the first potential. A second well region of the second conductivity type is disposed adjacent to the first well region. The second well region includes a first portion and a second portion. The device also includes a drain region of the second conductivity type. At least a portion of the drain region is disposed within the first portion of the second well region. Additionally, the device includes a first doped region of the first conductivity type in the first portion of the second well region. The first doped region is adjacent to the drain region and electrically coupled to the drain region. The device also includes a second doped region of the second conductivity type within the second portion of the second well region. The second doped region is adjacent to the source region. The device further includes a switch device coupled to the second doped region. In the semiconductor device also includes a first transistor coupled to the switch device through the second doped region. The first transistor includes the first doped region, the second well region, and the first well region. A second transistor includes the second well region, the first well region, and the source region. The first and the second transistors are configured to provide a current path during an ESD event. According to embodiments of the invention, the current path is triggered at a lower trigger voltage than a conventional SCR ESD protection device.

In a specific embodiment of the device, the first conductivity type is p-type, and the second conductivity type is p-type. In an embodiment, the first potential is a ground potential. The switch device can be a diode. A first terminal of the diode is coupled to the second doped region and a second terminal of the diode is coupled to a power supply potential. In another embodiment, the switch device includes a MOSFET. A first terminal of the MOSFET is coupled to the second doped region, and a second terminal of the MOSFET is coupled to the first potential. A gate terminal of the MOSFET is electrically coupled to the drain region through a capacitor and electrically coupled to the first potential through a resistor.

In another embodiment of the semiconductor device, the semiconductor device includes a lateral double diffused MOSFET (LDMOS), which includes a channel region in a surface region in the first well region, a gate dielectric overlying the channel region, a field oxide region between the channel region and the drain region, and a gate electrode overlying the gate dielectric and the field oxide region. In another embodiment the semiconductor device includes a high voltage field transistor, which has a field oxide region in a surface region between the source region and the drain region. In yet another embodiment, the semiconductor device includes a low voltage MOSFET, which further includes a channel region in a surface region in the first well region between the source region and the drain region and a gate dielectric overlying the channel region, and a gate electrode overlying the gate dielectric. At least a portion of the drain region is within the first well region.

According to another embodiment, the invention provides a method for forming a semiconductor device. The method includes providing a first well region of a first conductivity type. The first well region includes a first well contact region of the first conductivity type for coupling to a first potential. The method includes forming a source region of the second conductivity type within the first well region. The source region is coupled to the first potential. The method also includes providing a second well region of the second conductivity type adjacent to the first well region. The second well region including a first portion and a second portion. The method further includes forming a drain region of the second conductivity type. At least a portion of the drain region is disposed within the first portion of the second well region. The method further includes adding a first doped region of the first conductivity type in the first portion of the second well region. The first doped region is adjacent to the drain region and electrically coupled to the drain region. Moreover, the method includes adding a second doped region of the second conductivity type within the second portion of the second well region. The second doped region is adjacent to the source region and provides a contact to a base region of the first transistor. Additionally, the method includes forming a switch device coupled to the second doped region. In the semiconductor device formed according to the method, the first portion, the first well region, and the source region form a first transistor. The first doped region, the second well region, and the first well region form a second transistor. When an ESC event occurs, a current flows through the first transistor, which causes the base-emitter junction of the second transistor to be forward biased. The second transistor is turned on. Thus the first and the second transistors are configured to provide a current path during an ESD event.

In a specific embodiment of the method, the first conductivity type is p-type, and the second conductivity type is p-type. The first potential is a ground potential. In an embodiment, the switch device includes a diode. A first terminal of the diode is coupled to the second doped region and a second terminal of the diode is coupled to a power supply potential. The switch device includes a MOSFET. A first terminal of the MOSFET is coupled to the second doped region, and a second terminal of the MOSFET is coupled to the first potential. A gate terminal of the MOSFET is electrically coupled to the drain region through ha capacitor and electrically coupled to the first potential through a resistor.

In another embodiment, the method also includes forming a lateral double diffused MOSFET (LDMOS), which includes a channel region in a surface region in the first well region, a gate dielectric overlying the channel region, a field oxide region between the channel region and the drain region, and a gate electrode overlying the gate dielectric and the field oxide region. In another embodiment, the method includes forming a high voltage field transistor, which has a field oxide region in a surface region between the source region and the drain region. In yet another embodiment, the method includes forming a low voltage MOSFET, which further includes a channel region in a surface region in the first well region between the source region and the drain region, a gate dielectric overlying the channel region, and a gate electrode overlying the gate dielectric. At least a portion of the drain region is formed within the first well region.

According to an alternative embodiment, a semiconductor device includes a p-type well region, which has a first well contact for coupling to a ground potential. The device includes an n-type source region within the p-type well region. The source region is coupled to the ground potential. The device includes an n-type well region adjacent to the p-type well region. The n-type well region includes a first portion and a second portion. The device also includes an n-type drain region. At least a portion of the drain region is within the first portion of the n-type well region. The p-type doped region is adjacent to the drain region and electrically coupled to the drain region. The device also includes an n-type doped region within the second portion of the n-type well region. The n-type doped region is adjacent to the source region. The device further includes a switch device coupled to the n-type doped region. Additionally, the device includes two transistors. The first transistor includes the p-type doped region, the n-type well region, and the p-type well region. The first transistor is coupled to the switch device through the n-type doped region. The second transistor includes the n-type drain region, the p-type well region, and the n-type source region. When an ESC event occurs, a current path is provided to turn on the first transistor. The base-emitter junction of the second transistor is forwarded biased, and the second transistor is also turned on. Thus, the first and the second transistors provide a current path during an ESD event.

In a specific embodiment the switch device includes a diode. A first terminal of the diode is coupled to the second doped region, and a second terminal of the diode is coupled to a power supply potential. In another embodiment, the switch device includes a MOSFET. A first terminal of the MOSFET is coupled to the second doped region, and a second terminal of the MOSFET is coupled to the first potential. In an embodiment, a gate terminal of the MOSFET is electrically coupled to the drain region through a capacitor and electrically coupled to the first potential through a resistor.

Many benefits are achieved by way of the present invention over conventional techniques. For example, in an embodiment, the invention provides ESD protection structures having lower trigger voltages for improved ESD protection. In specific embodiments, the improved ESD protection structures include a switch device coupled to an ESD current path. In various embodiments, the invention provides improved ESD protection structures for various devices, such as LDMOS, high voltage field transistor, and low voltage MOSFET. Additionally, the invention provides a method for forming improved ESD protection structures that can be implemented using convention process technologies without substantial modifications to conventional equipment and processes. Depending upon the embodiment, one or more of these benefits may be achieved. These and other benefits will be described in more detail throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified cross-sectional view diagram of a lateral double diffused MOSFET (LDMOS) device according to an embodiment of the present invention;

FIG. 2 is a simplified layout diagram of the LDMOS device of FIG. 1 according to an embodiment of the present invention;

FIG. 3 is a simplified schematic diagram of the LDMOS device of FIG. 1 according to an embodiment of the present invention;

FIG. 4 is a simplified cross-sectional view diagram of the LDMOS device according to another embodiment of the present invention;

FIG. 5 is a simplified cross-sectional view of a high voltage field transistor according to an embodiment of the present invention;

FIG. 6 is a simplified cross-sectional view diagram of a low voltage MOS device according to another embodiment of the present invention;

FIG. 7 is a simplified layout diagram of a low voltage MOSFET device of FIG. 6 according to an embodiment of the present invention;

FIG. 8 is a simplified cross-sectional view diagram of an LDMOS device according to another embodiment of the present invention;

FIG. 9 is a simplified layout diagram of the LDMOS device of FIG. 8 according to an embodiment of the present invention;

FIG. 10 is a simplified schematic diagram of the LDMOS device of FIG. 8 according to an embodiment of the present invention;

FIG. 11 is a simplified cross-sectional view diagram of an LDMOS device according to an alternative embodiment of the present invention;

FIG. 12 is a simplified cross-sectional view diagram of a high voltage field transistor of FIG. 11 according to another embodiment of the present invention;

FIG. 13 is a simplified cross-sectional view diagram of a low voltage MOSFET device according to another embodiment of the present invention;

FIG. 14 is a simplified layout diagram of the low voltage MOSFET device of FIG. 13 according to an embodiment of the present invention; and

FIG. 15 is a simplified flow chart for a method for forming a semiconductor device including an ESD protection structure according to an embodiment of the present invention.

### DETAILED DESCRIPTION OF THE INVENTION

The present invention is directed to integrated circuits. More particularly, the invention provides a method and device for integrated circuits having electrostatic discharge (ESD) protection structure for providing an ESD current path which has a lower trigger voltage than a convention silicon controlled rectifier (SCR). Merely by way of example, the invention has been applied to LDMOS lateral double-diffused MOSFET (LDMOS), high voltage field transistors, and low voltage MOSFET for improved ESD protection. But it would be recognized that the invention has a much broader range of applicability.

As discussed above, conventional ESD protection device structures based on SCR often have high trigger voltages. In a conventional ESC protection structure, the SCR is often turned on, or triggered, if a high voltage at the drain contact pad is high enough to cause an avalanche breakdown at the junction between the n-well and p-substrate. This tends to result in a high trigger voltage, for example, 40-50V or higher. In many applications, such high trigger voltages do not provide adequate ESD protection to the integrated circuit. For example, in a 24V process technology, it is desireable to have an ESD protection device structure which has a trigger voltage of approximately 24 V. The conventional ESD protection structures also suffer from other limitations. Accordingly, an improved technique for ESD protection structures in semiconductor devices is highly desired.

Depending upon the embodiment, the present invention includes various features, which may be used. These features include the following:
1. ESD protection structures for providing a lower trigger voltage for improved ESD protection;
2. Improved ESD protection structures including a switch device coupled to an ESD current path;
3. Improved ESD protection structures for various devices, such as LDMOS, high voltage field transistor, and low voltage MOSFET; and
4. A method for forming improved ESD protection structures that can be implemented using conventional process technologies.

A shown, the above features may be in one or more of the embodiments to follow. These features are merely examples, which should not unduly limit the scope of the claims herein. One of ordinary skill in the art would recognize many variations, modifications, and alternatives.

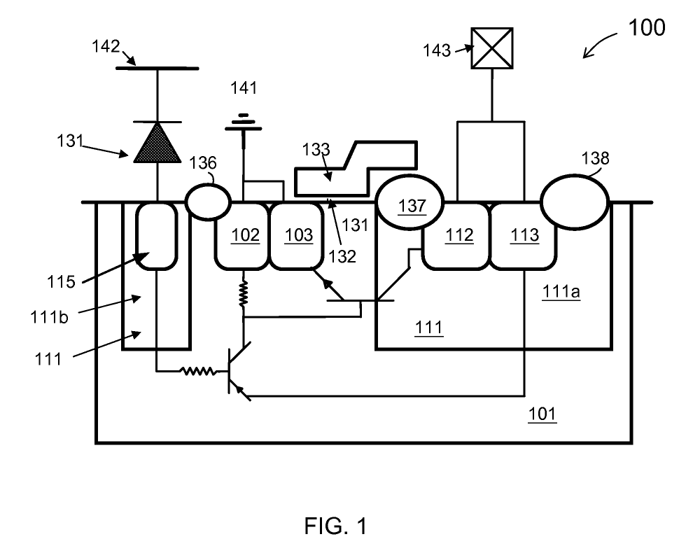

FIG. 1 is a simplified cross-sectional view diagram of a lateral double diffused MOSFET (LDMOS) device according to an embodiment of the present invention. This diagram is merely an example, which should not unduly limit the scope of the claims herein. One of ordinary skill in the art would recognize other variations, modifications, and alternatives. As shown, LDMOS device 100 is a semiconductor device, e.g. a silicon device, which includes a p-type well region 101. The p-type well region 101 includes a first well contact 102 for coupling to a ground potential 141. Device 100 also includes an n-type source region 103 within the p-type well region, and the source region is also coupled to the ground potential 141. Device 100 includes an n-type well region 111 adjacent to the p-type well region 101.

In the cross-sectional view of FIG. 1, n-type well region 111 is shown as two separate regions. In some embodiments, the n-type well region can include multiple regions which are contiguous. In FIG. 1, the first portion 111a is the n-well region on the right-hand side of the figure, and the second portion 111b is the n-well region on the left-hand side of the figure. In a specific embodiment, the first portion and the second portion are contiguous regions. Device 100 also includes an n-type drain region 112, and at least a portion of the drain region is within the n-type well region 111. In FIG. 1, the n-type drain region 112 is located within the first portion of the n-type well region 111a, but in other embodiments, part of the n-type drain region can be extended outside the n-type well region.

In FIG. 1, a p-type doped region 113 is disposed in the n-type well region 111. As shown, the p-type doped region 113 is adjacent to the drain region 112 and electrically coupled to the drain region 112. In some embodiments, the p-type dope region 113 may be positioned next to drain region 112, but in other embodiments, there can be a suitable distance between the p-type doped region 113 and the drain region 112 according to device or layout requirements. As shown in FIG. 1, the n-type drain region 112 and the p-type doped region 113 are electrically connected to a pad 143. Device 100 also includes an n-type doped region 115 within a portion of the n-type well region 111 which is close to the source region 103. Device 100 also includes a diode device 131 which electrically couples the n-type doped region 115 to a power supply potential 142 (VDD).

As shown in FIG. 1, the LDMOS 100 also includes a channel region 131 in a surface region in the p-type well region 101 and a gate dielectric 132 overlying the channel region. LDMOS also includes field oxide regions 136, 137, and 138. A gate electrode 133 overlies the gate dielectric 132 and field oxide region 133. As shown, field oxide region 137 is disposed between the channel region and the drain region.

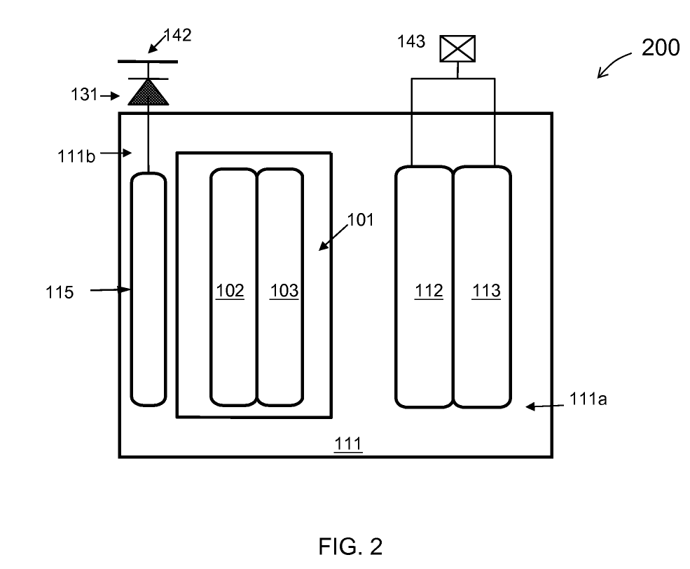

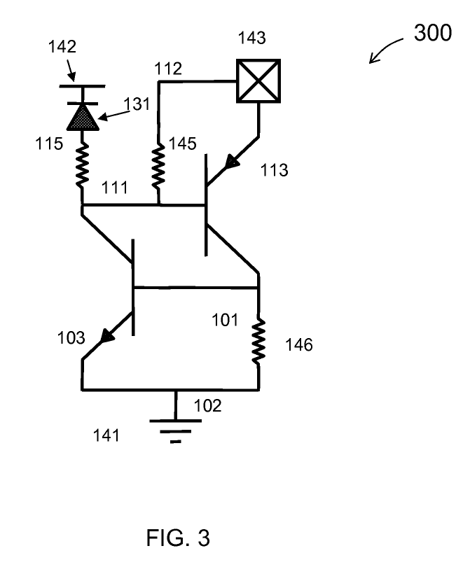

In FIG. 1, the p-type doped region 113, the first portion of the n-type well region 111a close to the drain region 112, and n-type well region 111 form a PNP transistor. Similarly, the n-type well region 111, the p-type well region 101 and the second portion of the n-type well region 111b close to the source region 103 form an NPN transistor. Further details of the LDMOS device are discussed below with reference to FIGS. 2 and 3.

FIG. 2 is a simplified layout diagram of the LDMOS device of FIG. 1 according to an embodiment of the present invention. This diagram is merely an example, which should not unduly limit the scope of the claims herein. In FIGS. 1 and 2, corresponding device regions are labeled with the same numerals. One of ordinary skill in the art would recognize other variations, modifications, and alternatives. As shown, the p-type well region 101 includes a first well contact 102 for coupling to a ground potential (not shown). The n-type source region 103 is located within the p-type well region. An n-type well region 111 is adjacent to the p-type well region 101 in FIG. 2, the p-type well region 101 is shown to be surrounded by the n-type well region 111. An n-type drain region 112 is located within the n-type well region 111.

In an embodiment, the n-well region includes a first portion and a second portion. In FIGS. 1 and 2, the first portion 111a is the n-well region on the right-hand side of the figure, and the second portion 111b is the n-well region on the left-hand side of the figure. In a specific embodiment, the first portion and the second portion are contiguous regions, as shown in FIG. 2.

In FIG. 2, a p-type doped region 113 is disposed in the n-type well region 111. As shown, the p-type doped region 113 is adjacent to the drain region 112 and electrically coupled to the drain region 112. In some embodiments, the p-type doped region 113 may be positioned next to drain region 112, but in other embodiments, there can be a suitable distance between the p-type doped region 113 and the drain region 112 according to device or layout requirements. The n-type drain region 112 and the p-type doped region 113 are electrically connected to a pad 143. In FIG. 2, several n-type doped regions 115 provide contact regions for the portion of the n-type well region 111 which is close to the source region 103. Diode device 131 electrically connects the n-type doped regions 115 to a power supply potential 142 (VDD).

In FIG. 2, the p-type doped region 113, the first portion of the n-type well region 111a close to the drain region 112, and n-type well region 111 form a PNP transistor. Similarly, the n-type well region 111, the p-type well region 1010 and the second portion of the n-type well region 111b close to the source region 103 form an NPN transistor. The various well regions and doped regions can be formed using conventional process technology. For example, doped regions 113 and 115 can be formed in an ion implantation process using appropriate p-type or n-type dopants. The operation of the transistors is discussed below with reference to the schematic diagram in FIG. 3.

FIG. 3 is a simplified schematic diagram of the LDMOS device of FIG. 1 according to an embodiment of the present invention. This diagram is merely an example, which should not unduly limit the scope of the claims herein. One of ordinary skill in the art would recognize other variations, modifications and alternatives. As shown, the p-type doped region 113, the n-type well region 111, and the p-type well region 101 form a PNP transistor. Similarly, the n-type well region 111, the p-type well region 101, and the source region 103 form an NPN bipolar transistor. Resistor R1 represents the resistance in the n-type well region, and resistor R2 represents the resistance in the p-type well region. The p-type doped region 113 is connected to pad 143, and the n-type doped region 115 is electrically connected to a diode 131 (D1). In an embodiment, diode 131 can be formed as a PN junction diode including two doped semiconductor regions. In an alternative embodiment, diode 131 can be a Schottky diode including a metal and a semiconductor.

When an ESD event occurs, a high voltage pulse appears on pad 143. A current may flow through the p-type doped region 113, the n-type well region 111, n-type doped region 115, and diode 131. The PNP transistor is turned on, and a forward bias is provided between the base terminal and the collector terminal of the NPN transistor. A current path is established from the n-type well region 111, through the p-type well region 101, and n-type source region 102 to the source terminal 141. As a result, the NPN transistor is triggered and the ESD current can be directed from the NPN transistor to the source or ground terminal 141. This conduction mechanism does not rely on avalanche breakdown between the n-type well and the p-type well. Therefore, this current conduction is enabled at a lower trigger voltage than conventional SCR structures, providing better device protection against ESC events. In a specific embodiment, the trigger voltage of about 25V has been obtained according to an embodiment of the invention. Of course, there can be other variations, modifications, and alternatives.

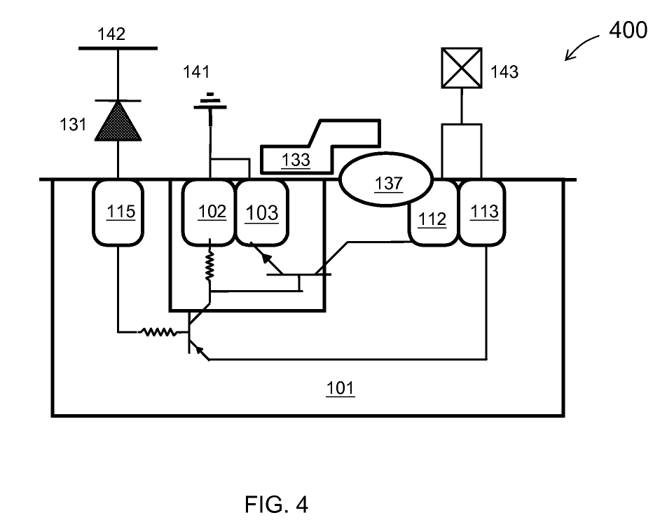

FIG. 4 is a simplified cross-sectional view diagram of the LDMOS device 400 according to another embodiment of the present invention. This diagram is merely an example, which should not unduly limit the scope of the claims herein. One of ordinary skill in the art would recognize other variations, modifications, and alternatives. As shown, LDMOS device 400 is similar to the LDMOS device 100 of FIG. 1, with a different well arrangement. As shown, p-well 101 is now formed inside n-well 111. Otherwise, the operation of LDMOS device 400 is similar to that of LDMOS device 100 discussed above. In particular, a PNP and an NPN transistors provide an ESD current path having a lower trigger voltage than conventional SCR devices.

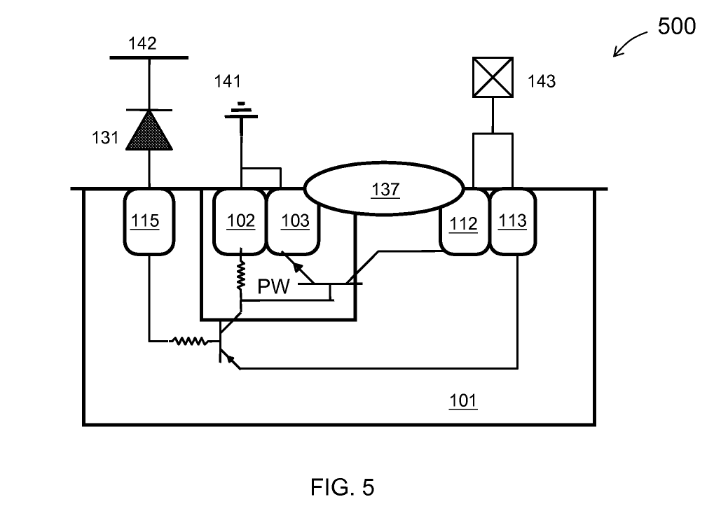

FIG. 5 is a simplified cross-sectional view of a high voltage field transistor according to an embodiment of the present invention. This diagram is merely an example, which should not unduly limit the scope of the claims herein. One of ordinary skill in the art would recognize other variations, modifications, and alternatives. As shown, field transistor 500 is similar to the LDMOS device 400 of FIG. 4, with a different gate arrangement. As shown, the field oxide 137 forms the gate dielectric of the high voltage field transistor. Otherwise, the ESD protection operation of field transistor 500 is similar to that of LDMOS devices 400 and 100 discussed above. In particular, a PNP and an NPN transistors provide an ESD current path having a lower trigger voltage than conventional SCR devices.

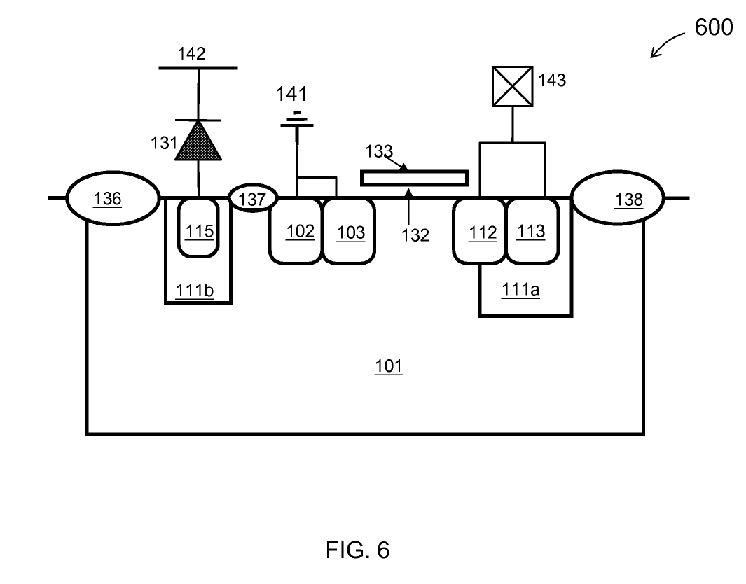

FIG. 6 is a simplified cross-sectional view diagram of a low voltage MOSFET device according to another embodiment of the present invention. This diagram is merely an example, which should not unduly limit the scope of the claims herein. One of ordinary skill in the art would recognize other variations, modifications, and alternatives. As shown, low voltage MOSFET 600 is similar to the LDMOS device 100 of FIG. 1, with low voltage MOSFET replacing the LDMOS. As shown, gate 133 now overlies gate dielectric 132, and drain region 112 resides partly in the p-type well 101 and partly in the n-type well 111. Otherwise, the ESD protection operation of LDMOS device 400 is similar to that of LDMOS device 100 discussed above. In particular, a PNP and an NPN transistors provide an ESD current path having a lower trigger voltage than conventional SCR devices.

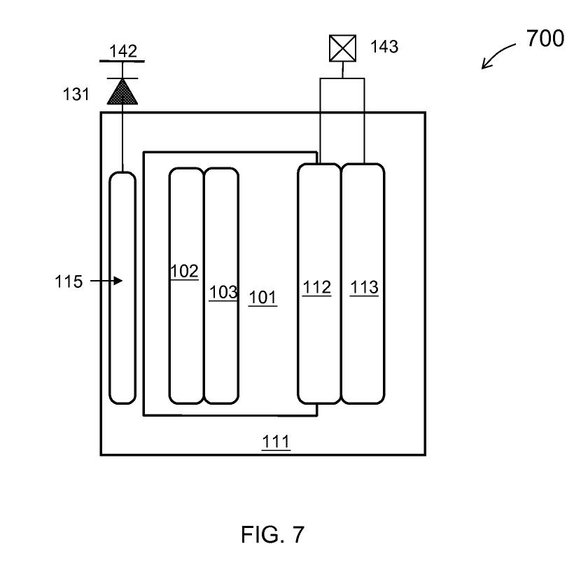

FIG. 7 is a simplified layout diagram of a low voltage MOSFET device of FIG. 6 according to an embodiment of the present invention. This diagram is merely an example, which should not unduly limit the scope of the claims herein. One of ordinary skill in the art would recognize other variations, modifications, and alternatives. As shown, the layout diagram is similar to the layout diagram of FIG. 2 for LDMOS device 100 with drain region 112 now residing partly in the p-type well 101 and partly in the n-type well 111.

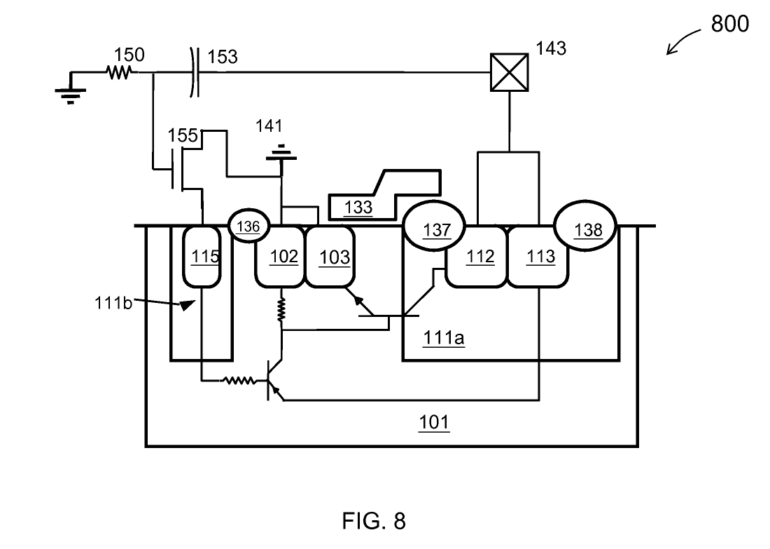

FIG. 8 is a simplified cross-section view diagram of an LDMOS device according to another embodiment of the present invention. This diagram is merely an example, which should not unduly limit the scope of the claims herein. One of ordinary skill in the art would recognize other variations, modifications, and alternatives. As shown, LDMOS device 800 is similar to LDMOS device 100 of FIG. 1, with an RC-triggered MOSFET replacing the diode as the switch device coupled to an ESD current path. In FIG. 8, an ESD current path is provided by an RC triggered MOSFET, including resistor R1, capacitor C1, and n-type MOSFET N1. According to embodiments of the invention, the resistance of R1 and the capacitance of C1 are selected such that MOSFET N1 is turned on by the high voltage pulse of an ESD event, providing a current path from the pad through the parasitic forward diode and also through N1 to a ground potential. During normal device operation, MOSFET N1 remains turned off, and no current flows through N1. Accordingly, p-type doped region 113, p-type well region 101, n-type well region 111, n-type doped region 115, and the RC-triggered MOSFET provide a current path. This current flow provides a positive bias at the base-collector junction of NPN transistor formed by n-type well region 111, p-type well region 101, and n-type doped region 103. The NPN transistor is then triggered to provide a current path for the ESC current. As discussed above, this design enables a reduced trigger voltage than conventional SCR devices. In an embodiment, MOSFET N1, resistor R1, and capacitor C1 can be formed in the same semiconductor substrate as the LDMOS using conventional integrated circuit process technology.

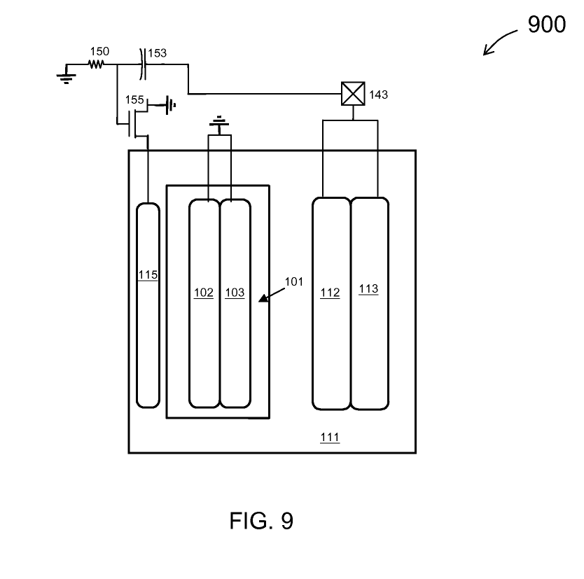

FIG. 9 is a simplified layout diagram of the LDMOS device of FIG. 8 according to an embodiment of the present invention. This diagram is merely an example, which should not unduly limit the scope of the claims herein. One of ordinary skill in the art would recognize other variations, modifications, and alternatives. As shown, the layout diagram in FIG. 9 is similar to the layout diagram in FIG. 2, with an RC-triggered MOSFET replacing the diode as the switch device coupled to an ESD current path.

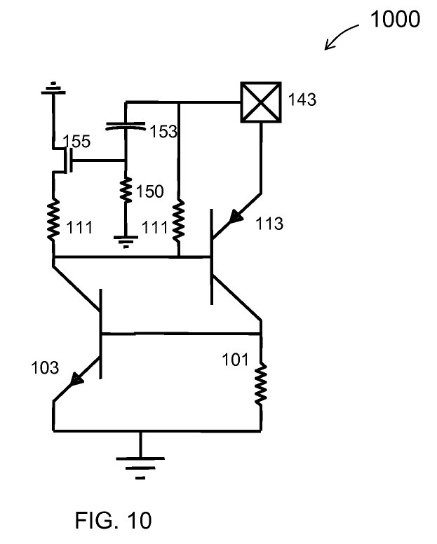

FIG. 10 is a simplified schematic diagram of the LDMOS device of FIG. 8 according to an embodiment of the present invention. This diagram is merely an example, which should not unduly limit the scope of the claims herein. One of ordinary skill in the art would recognize other variations, modifications, and alternatives. As shown, the schematic diagram in FIG. 10 is similar to the schematic diagram in FIG. 3, with an RC-triggered MOSFET replacing the diode as the switch device coupled to an ESD current path.

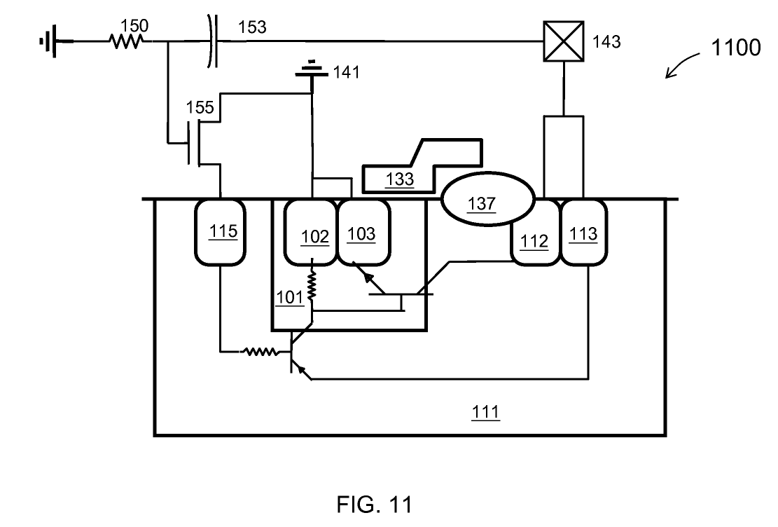

FIG. 11 is a simplified cross-sectional view diagram of an LDMOS device according to an alternative embodiment of the present invention. This diagram is merely an example, which should not unduly limit the scope of the claims herein. One of ordinary skill in the art would recognize other variations, modifications, and alternatives. As shown, LDMOS device 1100 is similar to the LDMOS device 400 of FIG. 4, with an RC-triggered MOSFET replacing the diode as the switch device coupled to the current path. The ESD protection operation of LDMOS device 1100 is similar to that LDMOS device 800 discussed above. In particular, two transistors provide an ESD current path having a lower trigger voltage than conventional SCR devices.

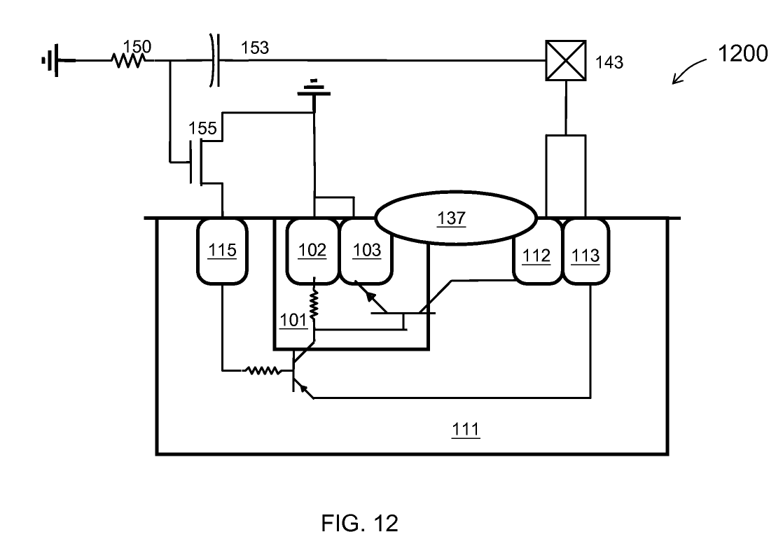

FIG. 12 is a simplified cross-sectional view diagram of a high voltage field transistor of FIG. 11 according to another embodiment of the present invention. This diagram is merely an example, which should not unduly limit the scope of the claims herein. One of ordinary skill in the art would recognize other variations, modifications, and alternatives. As shown, field transistor 1200 is similar to the field transistor 500 of FIG. 5, with an RC-triggered MOSFET replacing the diode as the switch device coupled to an ESD current path. The ESD protection operation of field transistor 1200 is similar to that of LDMOS device 800 discussed above. In particular, a transistor provides an ESD current path having a lower trigger voltage than conventional SCR devices.

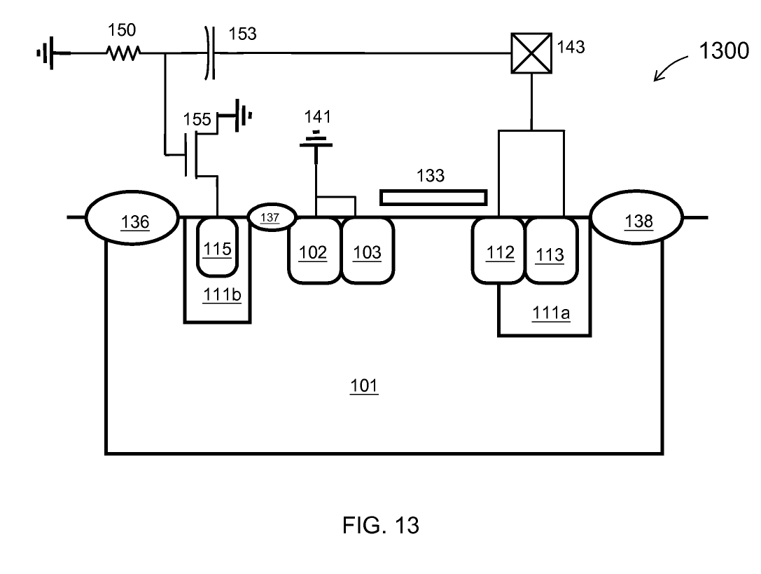

FIG. 13 is a simplified cross-sectional view diagram of a low voltage MOSFET device according to another embodiment of the present invention. This diagram is merely an example, which should not unduly limit the scope of the claims herein. Once of ordinary skill in the art would recognize other variations, modifications, and alternatives. As shown, low voltage MOSFET device 1300 is similar to the low voltage MOSFET device 600 of FIG. 6, with an RC-triggered MOSFET replacing the diode as the switch device coupled to an ESD current path. The ESC protection operation of low voltage MOSFET device 1300 is similar to that of LDMOS device 800 discussed above. In particular, two transistors provide an ESD current path having a lower trigger voltage than conventional SCR devices.

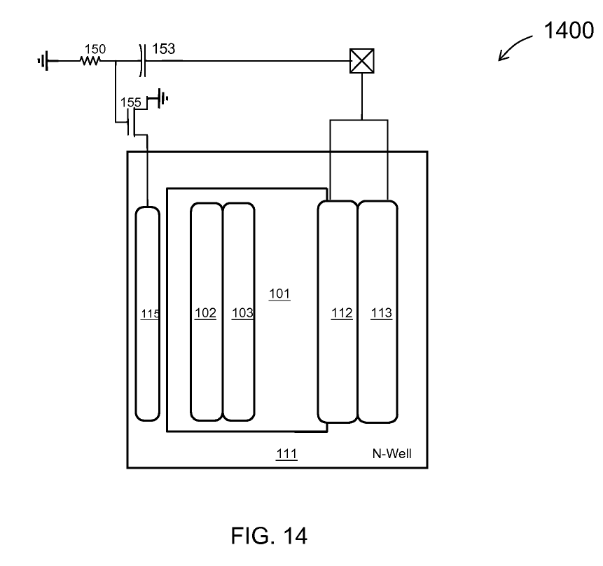

FIG. 14 is a simplified layout diagram of the low voltage MOSFET device of FIG. 13 according to an embodiment of the present invention. This diagram is merely an example, which should not unduly limit the scope of the claims herein. One of ordinary skill in the art would recognize other variations, modifications, and alternatives. As shown, the layout diagram for low voltage MOSFET device 1300 is similar to the layout diagram in FIG. 7 for the low voltage MOSFET device 600 of FIG. 6, with an RC-triggered MOSFET replacing the diode as the switch device.

Although the above has been shown using a selected group of components for providing ESD protection structures having reduced trigger voltages, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification and more particularly below.

According to an embodiment of the present invention, a method for forming a semiconductor device including an ESD protection structure can be briefly outlined below.
1. Provide a first well region of a first conductivity type;
2. Form a source region of the second conductivity type within the first well region;
3. Provide a second well region of the second conductivity type adjacent to the first well region;
4. Form a drain region of the second conductivity type;
5. Add a first doped region of the first conductivity type the first portion of the second well region;
6. Add a second doped region of the second conductivity type within the second portion of the second well region; and
7. Form a switch device coupled to the second doped region.

The above sequence of processes provides a method for forming a semiconductor device including an ESD protection structure according to an embodiment of the present invention. As shown, the method uses a combination of steps including a way of adding doped regions and electrically connecting a switch device to an ESD structure. Other alternatives can also be provided where steps are added, one or more steps are removed, or one or more steps are provided in a different sequence without departing from the scope of the claims herein. Further details of the present method can be found throughout the present specification and more particularly below.

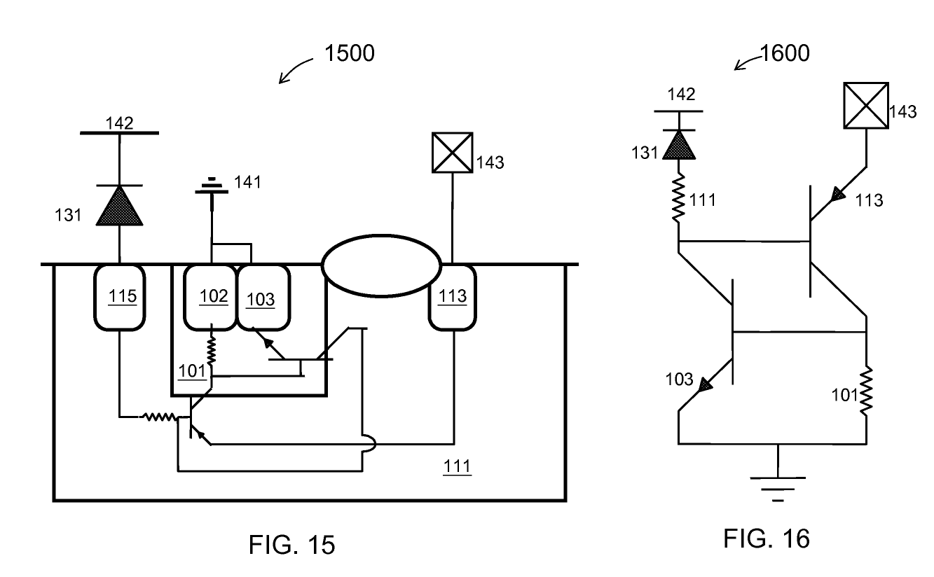

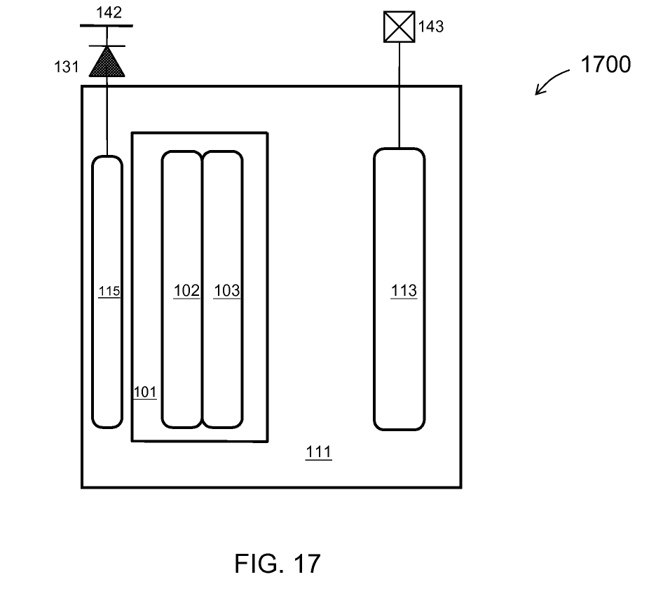

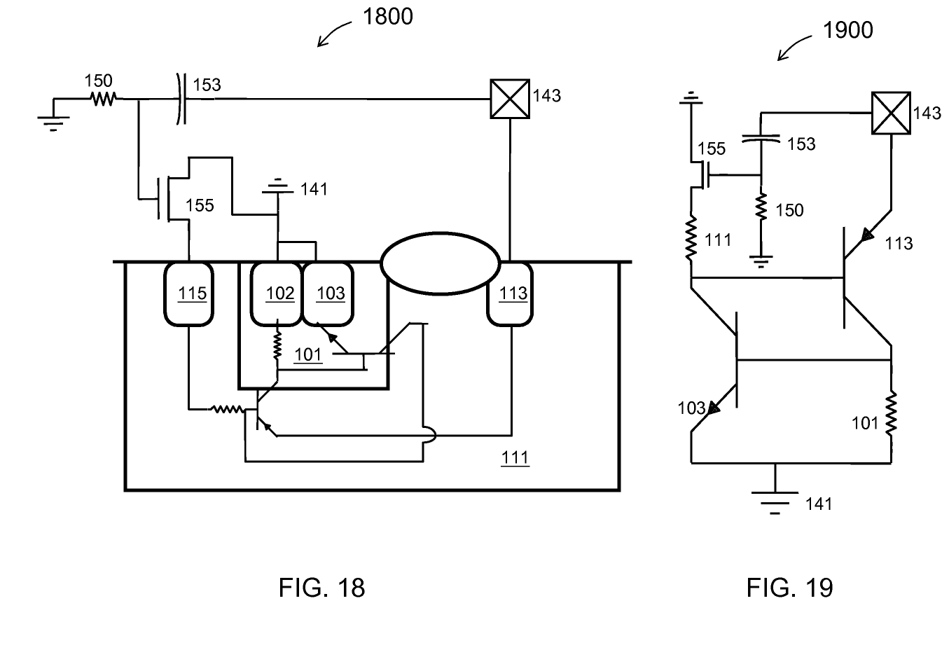

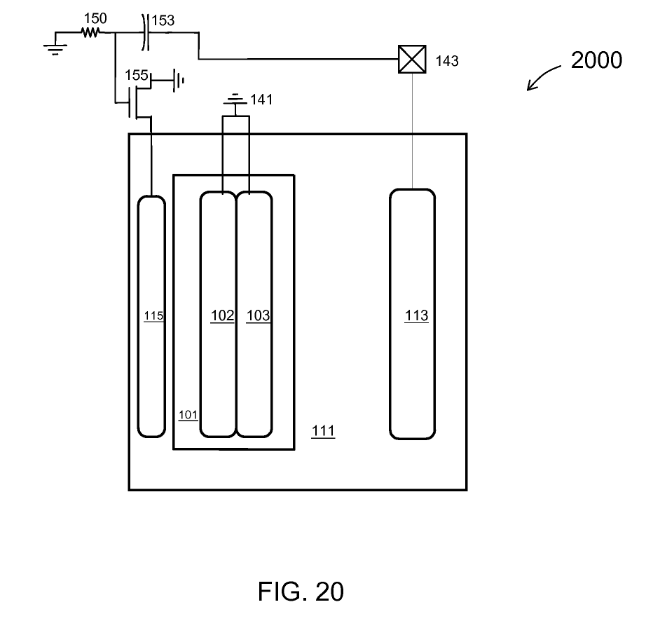

FIG. 15 is a simplified flow chart 1500 for a method for forming a semiconductor device including an ESD protection structure according to an embodiment of the present invention. This diagram is merely an example, which should not unduly limit the scope of the claims herein. One of ordinary skill in the art would recognize other variations, modifications, and alternatives. More details of the method are provided below with reference to FIGS. 1-14 and the accompanying text discussed above.

As shown in FIG. 15, the method includes providing a first well region (process 1501). In an embodiment, the first well region is characterized by a first conductivity type, for example, p-type. The first well region includes a first well contact region of the first conductivity type for coupling to a first potential, for example, a ground potential. An example of the first well region can be found in FIGS. 1 and 2.

The method includes forming a source region (process 1502). In an embodiment, the source region has the second conductivity type, e.g. n-type, within the first well region. The source region is coupled to the first potential, e.g. the ground potential. In FIGS. 1 and 2, the source region is shown as 103.

In process 1503, the method includes providing a second well region of the second conductivity type, for example, an n-well. In an embodiment, the second well region is adjacent to the first well region. The second well region includes a first portion and a second portion. In FIGS. 1 and 2, the first portion 111a is the n-well region on the right-hand side of the figure, and the second portion 111b is the n-well region on the left-hand side of the figure. In some embodiments, the first portion and the second portion are electrically connected. In a specific embodiment, the first portion and the second portion are contiguous regions, as shown in FIG. 2.

In process 1504, the method includes forming a drain region of the second conductivity type, e.g. n-type. In an embodiment, at least a portion of the drain region is within the first portion of the second well region. In FIGS. 1 and 2, the drain region is shown as 112.

The method also includes adding a first doped region of the first conductivity type the first portion of the second well region (process 1505). The first doped region is adjacent to the drain region and electrically coupled to the drain region. For example, in FIG. 2 the first doped region is the p+ region 113.

The method further includes adding a second doped region of the second conductivity type within the second portion of the second well region (process 1506). The second doped region is disposed adjacent to the source region. For example, in FIG. 2 the second doped region refers to one of the n+ regions 115.

In process 1507, the method includes forming a switch device coupled to the second doped region. Depending on the embodiments, the switch device can be a diode which provides a one-way conduction path, or a transistor in which a conduction path is controlled by a gate signal. The switch device can also be other types of semiconductor switch device.

In the device formed by the method discussed above, the first portion of the second well region, the first well region, and the source region form a first transistor. The first doped region, the second well region, and the first well region a second transistor. For example, a simplified schematic diagram is shown in FIG. 3. As discussed above in connection with FIG. 3, a current path during an ESD event is provided through the NPN transistor and PNP transistor. A lower trigger voltage can be provided than in a conventional SCR device.

In a specific embodiment, the switch device includes a diode. The first terminal of the diode is coupled to the second doped region and a second terminal of the diode is couple to a power supply potential. For example, in FIGS. 1 and 2, the switch device is diode D1 (131).

In an alternative embodiment, the switch device includes a MOSFET. A first terminal of the MOSFET is coupled to the second doped region and a second terminal of the MOSFET is coupled to the first potential. In a specific embodiment, a gate terminal of the MOSFET is electrically coupled to the drain region through a capacitor and electrically coupled to the first potential through a resistor. For example, in FIGS. 8 and 9, the switch device is MOSFET N1 coupled to resistor R1 and capacitor C1.

In an embodiment, the method also includes forming a lateral double diffused MOSFET (LDMOS), which includes a channel region in a surface region in the first well region, a gate dielectric overlying the channel region, a field oxide region between the channel region and the drain region, and a gate electrode overlying the gate dielectric and the field oxide region. Examples of an LDMOS are shown in FIGS. 1-4 and 8-11.

In another embodiment, the method includes forming a high voltage field transistor, the high voltage field transistor including a field oxide region in a surface region between the source region and the drain region. Examples of high voltage field transistor are show in FIGS. 5 and 12.

In an alternative embodiment, the method includes forming a low voltage MOSFET, which includes a channel region in a surface region in the first well region between the source region and the drain region, a gate dielectric overlying the channel region, and a gate electrode overlying the gate dielectric. In the low voltage MOSFET, at least a portion of the drain region is within the first well region. Examples of the low voltage MOSFET are shown in FIGS. 6, 7, 13, and 14.

The above sequence of processes provides a method for forming a semiconductor device including an ESD protection structure according to an embodiment of the present invention. In the above method, the various processes can be performed using conventional integrated circuit process technology. For example, the various regions can be patterned by a lithograph process. The well regions, well contact regions, and doped regions can be formed by ion implantation and/or diffusion processes. Dielectrics and conductive layers can be formed using various deposition processes. Additionally, examples of device formed according to the method are shown in FIGS. 1-14.

While the preferred embodiments of the invention have been illustrated and described, it will be clear that the invention is not limited to these embodiments only. Numerous modifications, changes, variations, substitutions and equivalents will be apparent to those skilled in the art without departing from the spirit and scope of the invention as described in the claims.

What is claimed is:

1. A semiconductor device, comprising:
a first well region of a first conductivity type, the first well region including a first well contact region of the first conductivity type for coupling to a first potential;
a source region of the second conductivity type within the first well region, the source region being coupled to the first potential;
a second well region of the second conductivity type adjacent to the first well region, the second well region including a first portion and a second portion;
a drain region of the second conductivity type, at least a portion of the drain region being disposed within the first portion of the second well region;
a first doped region of the first conductivity type in the first portion of the second well region, the first doped region being adjacent to the drain region and electrically coupled to the drain region;
a second doped region of the second conductivity type within the second portion of the second well region, the second doped region being adjacent to the source region; and
a switch device coupled to the second doped region;
a first transistor coupled to the switch device through the second doped region, the first transistor comprising the first doped region, the second well region, and the first well region; and
a second transistor comprising the second well region, the first well region, and the source region, the first and the second transistors being configured for providing a current path during an ESD event.

2. The semiconductor device of claim 1 wherein the first conductivity type is p-type, and the second conductivity type is p-type.

3. The semiconductor device of claim 1 wherein the first potential is a ground potential.

4. The semiconductor device of claim 1 wherein the switch device comprises a diode, a first terminal of the diode being coupled to the second doped region and a second terminal of the diode being coupled to a power supply potential.

5. The semiconductor device of claim 1 wherein the switch device comprises a MOSFET, a first terminal of the MOSFET being coupled to the second doped region and a second terminal of the MOSFET being coupled to the first potential.

6. The semiconductor device of claim 5 wherein a gate terminal of the MOSFET is electrically coupled to the drain region through a capacitor and electrically coupled to the first potential through a resistor.

7. The semiconductor device of claim 1 wherein the semiconductor device comprises a lateral double diffused MOSFET (LDMOS), the LDMOS including:
a channel region in a surface region in the first well region;
a gate dielectric overlying the channel region;
a field oxide region between the channel region and the drain region; and
a gate electrode overlying the gate dielectric and the field oxide region.

8. The semiconductor device of claim 1 wherein the semiconductor device comprises a high voltage field transistor, the high voltage field transistor including a field oxide region in a surface region between the source region and the drain region.

9. The semiconductor device of claim 1 wherein the semiconductor device comprises a low voltage MOSFET, the low voltage MOSFET further comprising:
a channel region in a surface region in the first well region between the source region and the drain region;
a gate dielectric overlying the channel region; and a gate electrode overlying the gate dielectric,
wherein at least a portion of the drain region is within the first well region.

10. A method for forming a semiconductor device, comprising:
providing a first well region of a first conductivity type, the first well region including a first well contact region of the first conductivity type for coupling to a first potential;
forming a source region of the second conductivity type within the first well region, the source region being coupled to the first potential;
providing a second well region of the second conductivity type adjacent to the first well region, the second well region including a first portion and a second portion;
forming a drain region of the second conductivity type, at least a portion of the drain region being disposed within the first portion of the second well region;
adding a first doped region of the first conductivity type in the first portion of the second well region, the first doped region being adjacent to the drain region and electrically coupled to the drain region, the first doped region, the second well region, and the first well region comprising a first transistor;
adding a second doped region of the second conductivity type within the second portion of the second well region, the second doped region being adjacent to the source region, the second doped region providing a contact to a base region of the first transistor, the second well region, the first well region, and the source region comprising a second transistor; and
forming a switch device coupled to the second doped region;
wherein the first and the second transistors are configured for providing a current path during an ESD event.

11. The method of claim 10 wherein the first conductivity type is p-type, and the second conductivity type is p-type.

12. The method of claim 10 wherein the first potential is a ground potential.

13. The method of claim 10 wherein the switch device comprises a diode, a first terminal of the diode being coupled to the second doped region and a second terminal of the diode being coupled to a power supply potential.

14. The method of claim 10 wherein the switch device comprises a MOSFET, a first terminal of the MOSFET being coupled to the second doped region and a second terminal of the MOSFET being coupled to the first potential.

15. The method of claim 14 wherein a gate terminal of the MOSFET is electrically coupled to the drain region through a capacitor and electrically coupled to the first potential through a resistor.

16. The method of claim 10 further comprising forming a lateral double diffused MOSFET (LDMOS), the LDMOS including:
a channel region in a surface region in the first well region;
a gate dielectric overlying the channel region;
a field oxide region between the channel region and the drain region; and
a gate electrode overlying the gate dielectric and the field oxide region.

17. The method of claim 10 further comprising forming a high voltage field transistor, the high voltage field transistor including a field oxide region in a surface region between the source region and the drain region.

18. The method of claim 10 further comprising forming a low voltage MOSFET, the low voltage MOSFET including:
a channel region in a surface region in the first well region between the source region and the drain region;
a gate dielectric overlying the channel region; and a gate electrode overlying the gate dielectric,
wherein at least a portion of the drain region is within the first well region.

19. A semiconductor device, comprising:
a p-type well region, the p-type well region including a first well contact for coupling to a ground potential;
an n-type source region within the p-type well region, the source region being coupled to the ground potential;
an n-type well region adjacent to the p-type well region, the n-type well region including a first portion and a second portion;
an n-type drain region, at least a portion of the drain region being within the first portion of the n-type well region;
a p-type doped region in the first portion of the n-type well region, the p-type doped region being adjacent to the drain region and electrically coupled to the drain region;
an n-type doped region within the second portion of the n-type well region, the n-type doped region being adjacent to the source region;
a switch device coupled to the n-type doped region;
a first transistor coupled to the switch device through the n-type doped region, the first transistor comprising the p-type doped region, the n-type well region, and the p-type well region; and
a second transistor comprising the n-type drain region, the p-type well region, and the n-type source region, the first and the second transistors being configured for providing a current path during an ESD event.

20. The semiconductor device of claim 19 wherein the switch device comprises a diode, a first terminal of the diode being coupled to the n-type doped region and a second terminal of the diode being coupled to a power supply potential.

21. The semiconductor device of claim 19 wherein the switch device comprises a MOSFET, a first terminal of the MOSFET being coupled to the n-type doped region and a second terminal of the MOSFET being coupled to the ground potential.

22. The semiconductor device of claim 21 wherein a gate terminal of the MOSFET is electrically coupled to the drain region through a capacitor and electrically coupled to the ground potential through a resistor.
